(19) United States
(12) Patent Application Publication
(10) Pub. No.: US 2026/0287840 A1
(43) Pub. Date: Sep. 24, 2026

(54) OPTICAL PACKAGE STRUCTURE AND MANUFACTURING METHOD THEREOF

(71) Applicant: SILICONWARE PRECISION INDUSTRIES CO., LTD., Taichung City (TW)

(72) Inventors: Shuai-Lin LIU, Taichung City (TW); Hung-Kun CHEN, Taichung City (TW)

(73) Assignee: SILICONWARE PRECISION INDUSTRIES CO., LTD., Taichung City (TW)

(21) Appl. No.: 19/448,556

(22) Filed: Jan. 14, 2026

(30) Foreign Application Priority Data
Mar. 21, 2025 (TW) 114110788

(51) Int. Cl. G02B 6/43; G02B 6/42; H10W 70/63

(52) U.S. Cl. CPC G02B 6/43; G02B 6/4239; G02B 6/428; H10W 70/635

(57) ABSTRACT

An optical package structure is provided and includes a first optical package unit and a second optical package unit. The first optical package unit and the second optical package unit are communicatively connected to each other via an optical transmission element. This arrangement improves signal communication performance. A method of manufacturing the optical package structure is further provided.

### BACKGROUND

### 1. Technical Field

The present disclosure relates to a semiconductor package structure, and more particularly, to an optical package structure with optical components and a manufacturing method thereof.

### 2. Description of Related Art

With the booming development of the electronics industry, electronic products are gradually advancing toward multi-functionality and high performance. At present, the application of fifth-generation (5G) communication technology has expanded to various fields such as the Internet of Things (IoT), Industrial Internet of Things (IIoT), cloud computing, artificial intelligence (AI), autonomous vehicles, and medical care. Moreover, with the expansion of applications, a massive amount of data needs to be efficiently transmitted, processed, and stored. In particular, the demand for data transmission has surged significantly, leading the industry to replace electricity with light as the carrier for data transmission, thereby improving transmission capacity, efficiency, and distance, and reducing energy consumption during transmission. Against this backdrop, co-packaged optical devices have become a future trend in semiconductor and packaging technology development.

Please refer to FIG. 1A and FIG. 1B, which are respectively a top schematic view and a partial cross-sectional schematic view of a conventional co-packaged optical device 1.

As shown in FIG. 1A, in the conventional co-packaged optical device 1, a plurality of optical engines 11 and a conversion chip 12 are integrated on a circuit board 10. As shown in FIG. 1B, the conversion chip 12 is first disposed on a substrate 13, and then the conversion chip 12 is disposed on and connected to the circuit board 10 via the substrate 13. Each of the plurality of optical engines 11 includes a semiconductor chip 112 formed in a package structure 111 and an optical chip 113 disposed on and connected to the package structure 111. One end of the optical chip 113 is connected to an optical fiber 14, and a shelf 15 is provided beneath the junction between the optical chip 113 and the optical fiber 14, so that optical signals can be transmitted to the optical engine 11 for communication.

However, in the aforementioned co-packaged optical device, the optical chip and the conversion chip must transmit signals via the metal circuits within the circuit board and the substrate. This not only results in an excessively large and thick overall device size, hindering the miniaturization of electronic products, but also leads to excessively long signal transmission paths, easily causing signal loss and problems in end-product applications. Furthermore, there is a risk of the shelf being suspended, resulting in insufficient support for the optical fiber and potential breakage.

Therefore, how to overcome the problems of the aforementioned prior art has become an urgent issue to be addressed.

### SUMMARY

In view of the above-mentioned deficiencies of the prior art, the present disclosure provides an optical package structure, which comprises: a first optical package unit including a first electronic element and a first optical engine; a second optical package unit including a second electronic element and a second optical engine; and an optical transmission element having one end connected to the first optical engine of the first optical package unit and the other end connected to the second optical engine of the second optical package unit.

The present disclosure further provides a method of manufacturing an optical package structure, and the method comprises: providing a first optical package unit including a first electronic element and a first optical engine; providing a second optical package unit including a second electronic element and a second optical engine; and connecting the first optical package unit and the second optical package unit with an optical transmission element, wherein one end of the optical transmission element is connected to the first optical engine of the first optical package unit, and the other end of the optical transmission element is connected to the second optical engine of the second optical package unit.

In the aforementioned optical package structure and method, the first electronic element is a system-on-a-chip.

In the aforementioned optical package structure and method, the optical transmission element is an optical waveguide element or a dielectric slab waveguide.

In the aforementioned optical package structure and method, the first optical package unit further includes a carrying board for disposing the first electronic element and the first optical engine. The carrying board is an interposer having a plurality of conductive vias.

In the aforementioned optical package structure and method, the first optical package unit further includes an encapsulation layer encapsulating the first optical engine and the first electronic element.

In the aforementioned optical package structure and method, the first optical engine and the second optical engine each includes an optical component and a semiconductor element stacked on the optical component. The optical component has a plurality of conductive holes. The optical component is an optical chip or an optical module. The semiconductor element is an electronic integrated circuit element. The first optical engine and the second optical engine each further includes an optical element disposed on the optical component.

In the aforementioned optical package structure and method, the second optical package unit further includes another carrying board for disposing the second electronic element and the second optical engine.

In the aforementioned optical package structure and method, the second electronic element is a high-bandwidth memory.

In the aforementioned optical package structure and method, the first optical package unit and the second optical package unit are disposed on a circuit board.

As can be seen from the above, in the optical package structure and manufacturing method thereof of the present disclosure, an electronic element is disposed on a carrying board, and an optical component and a semiconductor element are sequentially stacked on the carrying board to form a three-layer vertically stacked optical engine. At the same time, by forming a plurality of conductive holes in the optical component and a plurality of conductive vias in the carrying board, the optical component, the semiconductor element, the electronic element, and the carrying board can be directly electrically connected to each other via the plurality of conductive holes and the plurality of conductive vias, thereby shortening the signal transmission path between them and improving the transmission speed. Moreover, the optical element is supported by the optical component and the carrying board, reducing the risk of breakage of the optical component. Furthermore, the optical package unit composed of the electronic element and the optical engine disposed on and connected to the carrying board can be jointly disposed on and connected to a circuit board with another optical package unit, and an optical transmission element can be used to connect the optical package unit and the another optical package unit, realizing optical communication between the plurality of optical package units, thereby improving signal communication performance.

### BRIEF DESCRIPTION OF THE DRAWINGS

FIG. 1A and FIG. 1B are respectively a plan schematic view and a partial cross-sectional schematic view of a conventional co-packaged optical device.

FIG. 2A to FIG. 2E are cross-sectional and top schematic views illustrating a method of manufacturing an optical package structure according to the present disclosure.

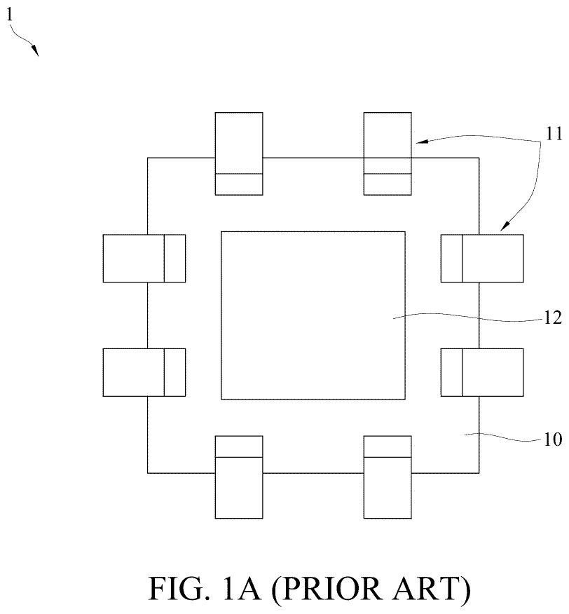

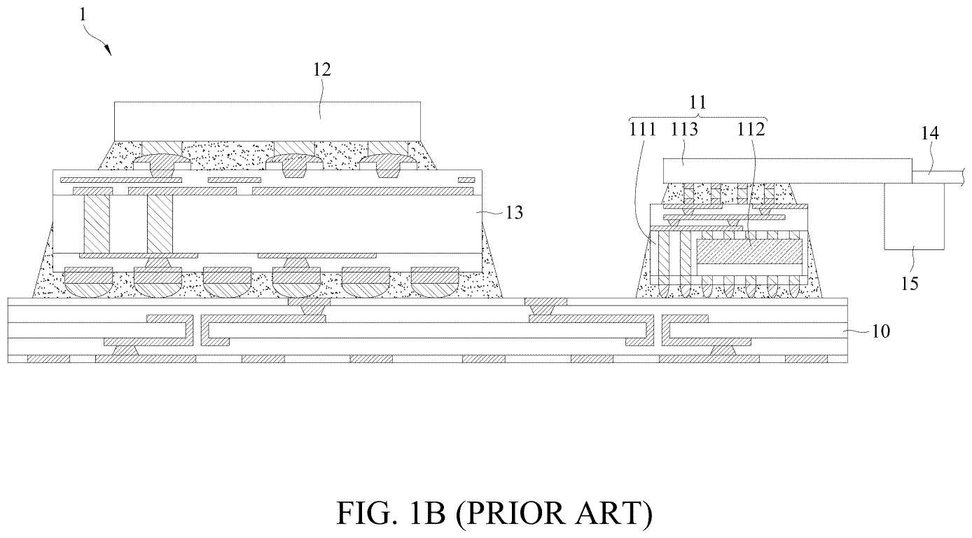

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “third,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

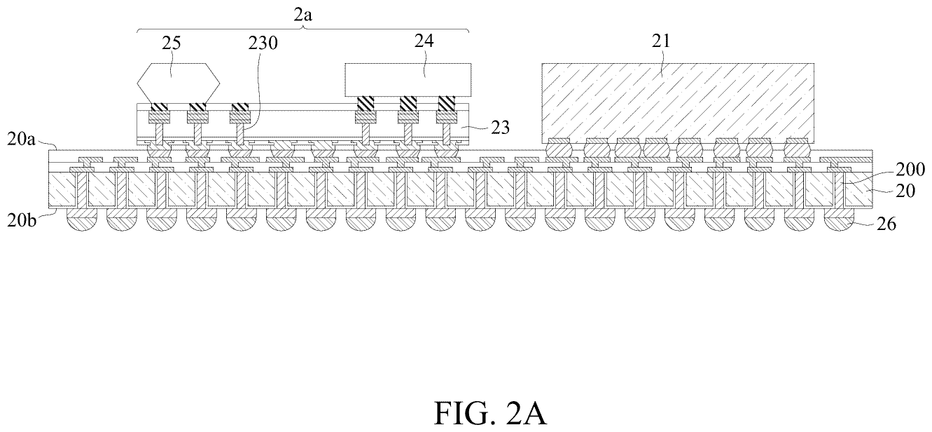

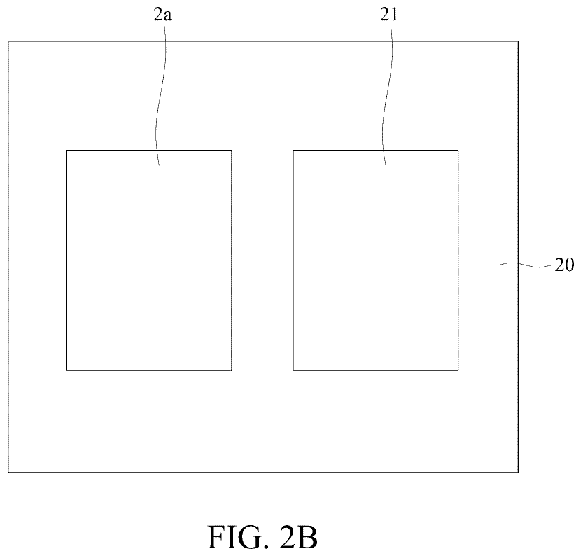

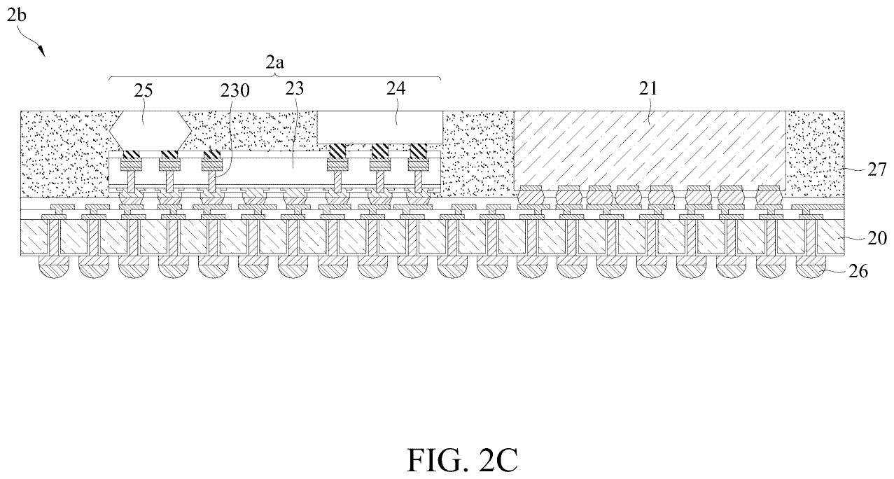

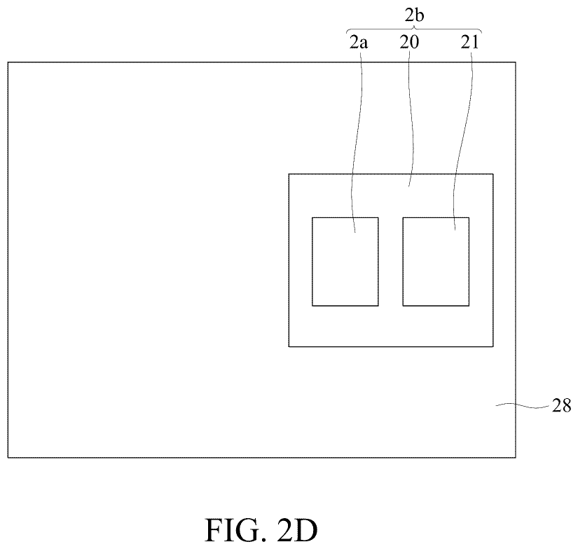

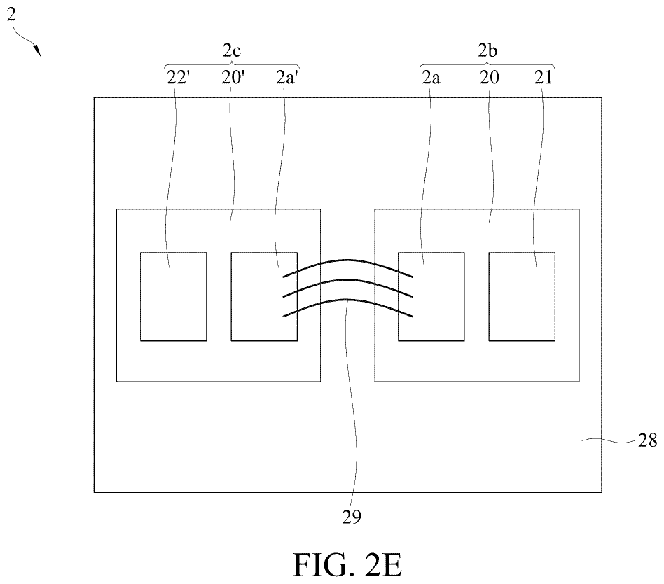

Please refer to FIG. 2A to FIG. 2E, which are cross-sectional and top schematic views illustrating a method of manufacturing an optical package structure 2 according to the present disclosure.

As shown in FIG. 2A, a carrying board 20 is provided. A first electronic element 21 and an optical component 23 are disposed on and electrically connected to the carrying board 20. A semiconductor element 24 and an optical element 25 are disposed on and electrically connected to the optical component 23.

The carrying board 20 is, for example, an interposer. A plurality of conductive vias 200 (e.g., conductive through-silicon vias) are formed in the carrying board 20. The carrying board 20 has a first side 20a and a second side 20b opposite to the first side 20a. The first electronic element 21 and the optical component 23 are disposed on the first side 20a of the carrying board 20. A plurality of conductive elements 26 (e.g., solder bumps or copper bumps) can be placed on the second side 20b of the carrying board 20.

In an embodiment, the first electronic element 21 is a system-on-a-chip (SoC), such as a switch application-specific integrated circuit (switch ASIC). The first electronic element 21 can be disposed on and electrically connected to the carrying board 20 via a plurality of conductive bumps.

A plurality of conductive holes 230 are formed in the optical component 23. The optical component 23 can be disposed on and electrically connected to the carrying board 20 via a plurality of conductive bumps.

In an embodiment, the optical component 23 is, for example, an optical chip (photonic integrated circuit [PIC]) or an optical module (PIC module). The optical module optionally includes a coupler, an optical chip, a total reflection mirror, a fiber array unit (FAU), etc.

The semiconductor element 24 is, for example, an electronic integrated circuit (EIC) element. The semiconductor element 24 can be disposed on and electrically connected to the optical component 23 via a plurality of conductive bumps.

The optical element 25 is, for example, an optical fiber socket, a lens, or a bracket. The optical element 25 is disposed on and connected to the optical component 23, and the optical element 25 is supported by the optical component 23 and the carrying board 20, thereby reducing the risk of breakage of the optical component 23 or the optical element 25. In other embodiments, the optical element 25 may be integrated into the optical component 23.

As shown in FIG. 2B, which is a top schematic view of FIG. 2A, in this embodiment, the optical component 23 and the semiconductor element 24 (and the optical element 25) constitute a first optical engine (OE) 2a. The first electronic element 21 and the first optical engine 2a are disposed on the same side of the carrying board 20 and are arranged adjacent to each other.

In the present disclosure, the plurality of conductive holes 230 formed in the optical component 23 are utilized to directly stack and electrically connect the semiconductor element 24, the optical component 23, and the carrying board 20, thereby forming a three-dimensional (3D) stacked structure to shorten the interconnection distance between the optical component 23 (PIC) and the semiconductor element 24 (EIC) and improve signal transmission efficiency. At the same time, the plurality of conductive vias 200 are formed in the carrying board 20 (interposer) to integrate the first electronic element 21 (SoC) and the first optical engine 2a (OE), thereby further shortening the signal transmission distance.

As shown in FIG. 2C, a packaging process is performed to form an encapsulation layer 27 on the carrying board 20. The encapsulation layer 27 encapsulates the first optical engine 2a and the first electronic element 21. The encapsulation layer 27 may be thinned, so that the optical element 25 is exposed from the encapsulation layer 27, thereby constituting a first optical package unit 2b. In an embodiment, an upper surface of the semiconductor element 24 and an upper surface of the first electronic element 21 are also exposed from the encapsulation layer 27.

As shown in FIG. 2D, a circuit board 28 is provided. The first optical package unit 2b is disposed on the circuit board 28. The first optical package unit 2b can be disposed on and electrically connected to the circuit board 28 via the plurality of conductive elements 26.

As shown in FIG. 2E, a second optical package unit 2c is provided. The second optical package unit 2c is disposed on and electrically connected to the circuit board 28. The second optical package unit 2c is arranged adjacent to the first optical package unit 2b, and the second optical package unit 2c and the first optical package unit 2b are communicatively connected to each other, thereby forming the optical package structure 2 of the present disclosure.

The second optical package unit 2c is formed and structured similarly to the first optical package unit 2b. The second optical package unit 2c includes another carrying board 20′ (e.g., an interposer having a plurality of conductive vias), and a second electronic element 22′ together with another optical engine, namely a second optical engine 2a′, disposed on the carrying board 20′. The second optical engine 2a′ includes an optical component having a plurality of conductive holes and a semiconductor element and an optical element disposed on the optical component, so that the second electronic element 22′ and the second optical engine 2a′ are integrated by means of the carrying board 20'. The second electronic element 22′ may be the same as the first electronic element 21 (e.g., a system-on-a-chip). In an embodiment, the second electronic element 22′ is different from the first electronic element 21; and the second electronic element 22′ is, for example, a high-bandwidth memory (HBM).

The first optical package unit 2b and the second optical package unit 2c can be directly communicatively connected to each other via at least one optical transmission element 29. In an embodiment, one end of the optical transmission element 29 (e.g., an optical waveguide element, a dielectric planar/slab waveguide, or an optical fiber) can be connected to the first optical engine 2a (optoelectronic accessory/component) of the first optical package unit 2b, and the other end of the optical transmission element 29 can be connected to the second optical engine 2a′ (optoelectronic accessory/component) of the second optical package unit 2c. This allows the first optical package unit 2b and the second optical package unit 2c to communicate optically, thereby avoiding the losses caused by conventional communication using the metal circuits.

Through the aforementioned manufacturing method, the present disclosure further discloses an optical package structure 2, which comprises: a first optical package unit 2b and a second optical package unit 2c; and an optical transmission element 29 communicatively connected to the first optical package unit 2b and the second optical package unit 2c.

The first optical package unit 2b includes a carrying board 20, and a first electronic element 21 and a first optical engine 2a disposed on the carrying board 20.

The second optical package unit 2c includes a carrying board 20′, and a second electronic element 22′ and a second optical engine 2a′ disposed on the carrying board 20′, such that one end of the optical transmission element 29 is connected to the first optical engine 2a of the first optical package unit 2b, and the other end of the optical transmission element 29 is connected to the second optical engine 2a′ of the second optical package unit 2c, thereby enabling optical communication between the first optical package unit 2b and the second optical package unit 2c. In addition, the first optical package unit 2b and the second optical package unit 2c are disposed on a circuit board 28.

To sum up, in the optical package structure and manufacturing method thereof of the present disclosure, an electronic element is disposed on a carrying board, and an optical component and a semiconductor element are sequentially stacked on the carrying board to form a three-layer vertically stacked optical engine. At the same time, by forming a plurality of conductive holes in the optical component and a plurality of conductive vias in the carrying board, the optical component, the semiconductor element, the electronic element, and the carrying board can be directly electrically connected to each other via the plurality of conductive holes and the plurality of conductive vias, thereby shortening the signal transmission path between them and improving the transmission speed. Moreover, the optical element is supported by the optical component and the carrying board, reducing the risk of breakage of the optical component. Furthermore, the optical package unit composed of the electronic element and the optical engine disposed on and connected to the carrying board can be jointly disposed on and connected to a circuit board with another optical package unit, and an optical transmission element can be used to connect the optical package unit and the another optical package unit, realizing optical communication between the plurality of optical package units, thereby improving signal communication performance.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An optical package structure, comprising:
a first optical package unit including a first electronic element and a first optical engine;
a second optical package unit including a second electronic element and a second optical engine; and
an optical transmission element having one end connected to the first optical engine of the first optical package unit and the other end connected to the second optical engine of the second optical package unit.

2. The optical package structure of claim 1, wherein the first electronic element is a system-on-a-chip.

3. The optical package structure of claim 1, wherein the optical transmission element is an optical waveguide element or a dielectric slab waveguide.

4. The optical package structure of claim 1, wherein the first optical package unit further includes a carrying board for disposing the first electronic element and the first optical engine.

5. The optical package structure of claim 4, wherein the carrying board is an interposer having a plurality of conductive vias.

6. The optical package structure of claim 4, wherein the first optical package unit further includes an encapsulation layer encapsulating the first optical engine and the first electronic element.

7. The optical package structure of claim 1, wherein the first optical engine and the second optical engine each includes an optical component and a semiconductor element stacked on the optical component.

8. The optical package structure of claim 7, wherein the optical component has a plurality of conductive holes.

9. The optical package structure of claim 7, wherein the optical component is an optical chip or an optical module.

10. The optical package structure of claim 7, wherein the semiconductor element is an electronic integrated circuit element.

11. The optical package structure of claim 7, wherein the first optical engine and the second optical engine each further includes an optical element disposed on the optical component.

12. The optical package structure of claim 1, wherein the second optical package unit further includes another carrying board for disposing the second electronic element and the second optical engine.

13. The optical package structure of claim 1, wherein the second electronic element is a high-bandwidth memory.

14. The optical package structure of claim 1, wherein the first optical package unit and the second optical package unit are disposed on a circuit board.

15. A method of manufacturing an optical package structure, comprising:
providing a first optical package unit including a first electronic element and a first optical engine;
providing a second optical package unit including a second electronic element and a second optical engine; and
connecting the first optical package unit and the second optical package unit with an optical transmission element, wherein one end of the optical transmission element is connected to the first optical engine of the first optical package unit, and the other end of the optical transmission element is connected to the second optical engine of the second optical package unit.

16. The method of claim 15, wherein the first electronic element is a system-on-a-chip.

17. The method of claim 15, wherein the optical transmission element is an optical waveguide element or a dielectric slab waveguide.

18. The method of claim 15, wherein the first optical package unit further includes a carrying board for disposing the first electronic element and the first optical engine.

19. The method of claim 18, wherein the carrying board is an interposer having a plurality of conductive vias.

20. The method of claim 18, wherein the first optical package unit further includes an encapsulation layer encapsulating the first optical engine and the first electronic element.

21. The method of claim 15, wherein the first optical engine and the second optical engine each includes an optical component and a semiconductor element stacked on the optical component.

22. The method of claim 21, wherein the optical component has a plurality of conductive holes.

23. The method of claim 21, wherein the optical component is an optical chip or an optical module.

24. The method of claim 21, wherein the semiconductor element is an electronic integrated circuit element.

25. The method of claim 21, wherein the first optical engine and the second optical engine each further includes an optical element disposed on the optical component.

26. The method of claim 15, wherein the second optical package unit further includes another carrying board for disposing the second electronic element and the second optical engine.

27. The method of claim 15, wherein the second electronic element is a high-bandwidth memory.

28. The method of claim 15, wherein the first optical package unit and the second optical package unit are disposed on a circuit board.
